(19) United States
(12) Patent Application Publication
(10) Pub. No.: US 2013/0126962 A1
(43) Pub. Date: May 23, 2013

(54) SEMICONDUCTOR DEVICE AND METHOD OF MANUFACTURING THE SAME

(71) Applicant: SK hynix Inc., Icheon-si (KR)

(72) Inventor: Seung Suk OH, Seoul (KR)

(73) Assignee: SK hynix Inc., Icheon-si (KR)

(21) Appl. No.: 13/682,671

(22) Filed: Nov. 20, 2012

(30) Foreign Application Priority Data
Nov. 21, 2011 (KR) 10-2011-0121694

(51) Int. Cl. H01L 21/20; H01L 29/78

(52) U.S. Cl. CPC H01L 21/20; H01L 29/7827
USPC 257/329; 438/478

(57) ABSTRACT

A semiconductor device and a method of manufacturing the same are provided. After spacers are formed on sidewalls of a pillar pattern and a photoresist pattern exposing an OSC formation region is formed on a semiconductor substrate including the pillar pattern and the spacer, processes for removing a spacer corresponding to the OSC formation region to form an OSC, removing the photoresist pattern, forming a bit line between the pillar patterns, an epitaxial layer on the pillar pattern, and forming a vertical gate and a storage node contact, are performed so that the OSC formation process can be simplified. In addition, the OSC formation process is performed in a state that the pillar pattern has a low height so that a failure such as a not-open failure caused in the OSC formation process can be prevented.

### CROSS-REFERENCES TO RELATED APPLICATION

The present application claims priority to Korean patent application number 10-2011-0121694 filed on Nov. 21, 2011, which is incorporated by reference in its entirety.

### BACKGROUND OF THE INVENTION

The present invention relates to a semiconductor device and a method of manufacturing the same.

In recent years, among semiconductor memory devices, dynamic random access memories (DRAMs), which have a flexible input/output (I/O) and are implemented with high capacity, have been widely used.

In general, each of the DRAM cells has a MOS transistor and a storage capacitor. The MOS transistor enables data charges in the storage capacitor to move in data read and write operations. In addition, a refresh operation which provides charges to the storage capacitor periodically is performed to prevent a data loss due to a leakage current in the DRAM cell.

To be highly integrated even when a size of the storage capacitor is reduced, DRAM should have a capacitor with a sufficient storage capacity and a small unit cell size. In particular, a general approach to reduce a production cost of DRAM is to increase an integration level. To improve an integration density of the DRAM cell, a unit cell size of the DRAM cell needs to be reduced. However, as a semiconductor device is shrunk, characteristics of the semiconductor devices are degraded by a short channel effect.

Conventionally, when a DRAM device is fabricated, the size of the DRAM cell is limited by a minimum pattern size (F) of a lithography feature. An 8F2 unit memory cell is used in the related art. Since a transistor has a channel region of a planar structure in the related art, the transistor has limitations in an integration level and in a current control.

To overcome the limitation, the transistor having a planar channel region is changed into a transistor having a three dimensional channel region such as a recess gate, a fin gate, or a buried gate type transistor. As the semiconductor device is further scaled down, the transistor having the three dimensional channel region reaches its minimum size limit.

To overcome the above minimum size limit, vertical transistors have been suggested. Source and drain regions are formed on a substrate in a horizontal direction in the conventional transistor and thus the channel region is formed laterally in the substrate. However, highly doped source and drain regions in the vertical transistors are formed in a vertical direction, and thus a channel region is vertically formed in a substrate.

It is difficult to control a body voltage in the vertical transistor having a channel region formed of an undoped silicon (Si) in the related art. Therefore, the vertical transistor has a difficulty in effectively controlling phenomena such as a punch-through effect or a floating body effect. That is, while the vertical transistor is not in operation, a gate induced drain leakage (GIDL) effect or a drain induced barrier lowering (DIBL) effect is caused due to holes accumulated in a body. Thereby, a current loss in the transistor frequently occurs and charges stored in a capacitor are drained so that a loss of original data is caused.

### BRIEF SUMMARY OF INVENTION

According to one aspect of an exemplary embodiment, a method of manufacturing a semiconductor device includes forming pillar patterns on a semiconductor substrate, forming spacers on sidewalls of each pillar pattern, forming a photoresist pattern exposing an one side contact (OSC) formation region, removing an exposed spacer of the spacers on each pillar pattern using the photoresist pattern as a barrier to form an OSC, forming a bit line pattern between the pillar patterns, forming a silicon pattern by growing silicon on each pillar pattern, forming a gate pattern connected to the pillar patterns in a vertical direction, and forming a contact on each pillar pattern.

The forming the pillar patterns may include forming a photoresist pattern on the semiconductor substrate, and etching the semiconductor substrate using a mask for pillar pattern formation as an etch mask.

The forming the pillar patterns may include anisotropically etching the semiconductor substrate.

The forming the spacers may include forming a liner insulating layer on the pillar patterns and the semiconductor substrate, and etching back the liner insulating layer.

The forming the OSC may include removing the exposed spacer by a cleaning process.

The forming the photoresist pattern may include forming the photoresist pattern exposing the exposed spacer of the spacers on one sidewall of each pillar pattern and shielding the other spacer of the spacers on the other sidewall of each pillar pattern.

The silicon pattern may be grown to a height of 100 nm to 200 nm.

According to another aspect of an exemplary embodiment, a semiconductor device includes pillar patterns disposed on a semiconductor substrate, a spacer disposed on one sidewall of each pillar pattern, an OSC disposed on the other sidewall of each pillar pattern, a bit line pattern between the pillar patterns, a silicon pattern disposed on each pillar pattern, a gate pattern connected to pillar patterns in a vertical direction, and a contact disposed on the silicon pattern.

The spacers may include an insulating layer.

The silicon pattern may have a height of 100 nm to 200 nm.

These and other features, aspects, and embodiments are described below in the section entitled “DESCRIPTION OF EMBODIMENTS”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A to 1I are cross-sections illustrating a method of manufacturing a semiconductor device according to an exemplary embodiment of the present invention;

FIG. 2 is a block diagram illustrating a configuration of a cell array according to an exemplary embodiment of the present invention;

FIG. 3 is a block diagram illustrating a configuration of a semiconductor device according to an exemplary embodiment of the present invention;

FIG. 4 is a block diagram illustrating a configuration of a semiconductor module according to an exemplary embodiment of the present invention;

FIG. 5 is a block diagram illustrating a configuration of a semiconductor system according to an exemplary embodiment of the present invention; and

FIG. 6 is a block diagram illustrating configurations of an electronic unit and an electronic system according to an exemplary embodiment of the present invention.

### DESCRIPTION OF EMBODIMENTS

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

Hereinafter, an exemplary embodiment of the present invention will be described in detail with reference to accompanying drawings.

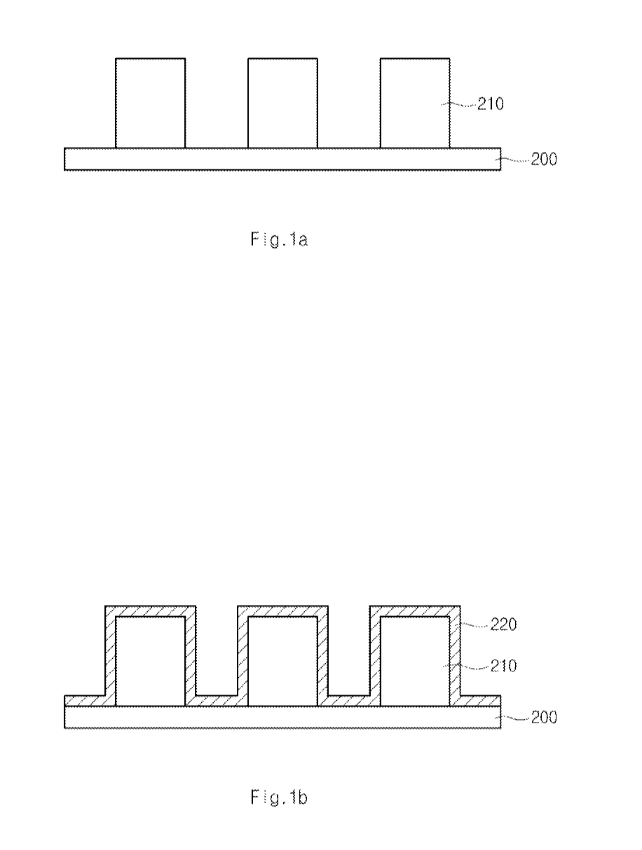

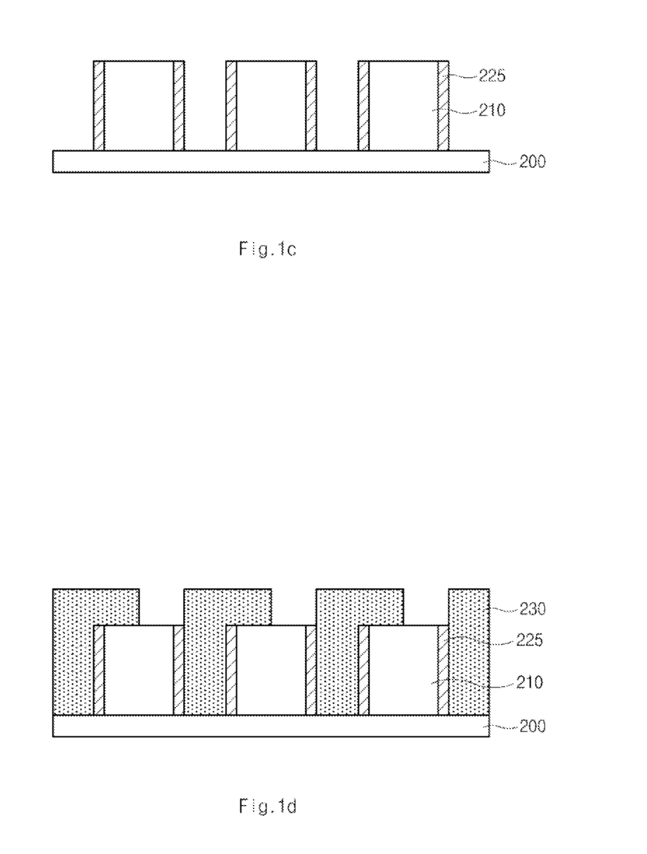

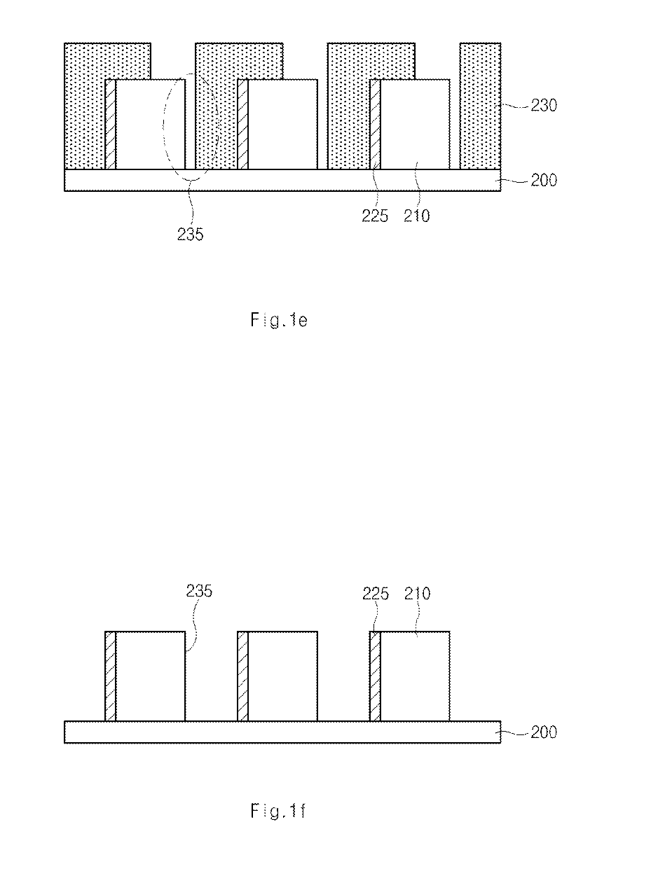

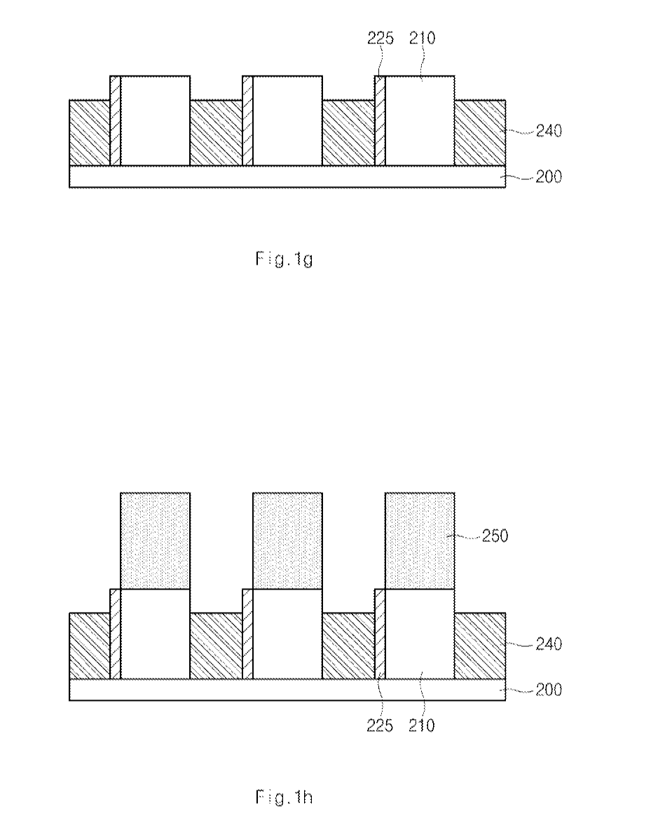

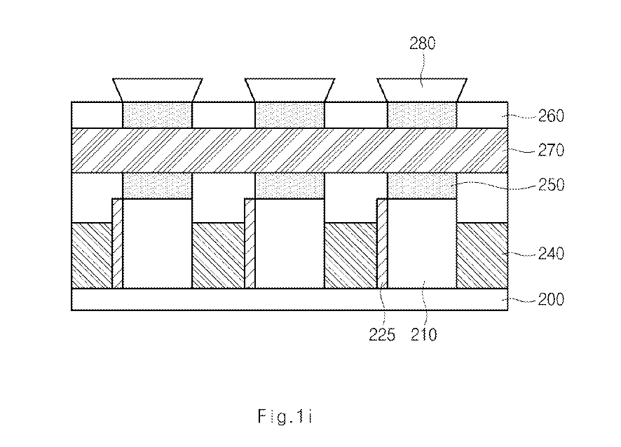

FIGS. 1A to 1I are cross-sectional views illustrating a method of manufacturing a semiconductor device according to an exemplary embodiment of the present invention.

Referring to FIG. 1A, a photoresist layer is formed on a semiconductor substrate 200 and patterned through an exposure and development process using a mask for pillar pattern formation to form a photoresist pattern (not shown). The semiconductor substrate 200 is etched using the photoresist pattern as an etch mask to form pillar patterns 210. The pillar pattern 210 may be formed of a silicon (Si) pillar. In an embodiment, a height of the pillar pattern 210 may be smaller than that in the related art. The height of the final pillar pattern 210 may be adjusted by reducing an etch rate of the semiconductor substrate 200. When a one side contact (OSC) is formed in a subsequent process, an etching failure where the OSC is not open due to a short pillar pattern can be prevented.

Referring to FIG. 1B, a liner oxide layer 220 is formed on the pillar patterns 210 and the semiconductor substrate 200.

Referring to FIG. 1C, the liner oxide layer 220 is etched back until the pillar patterns are exposed, thereby forming first and second spacers 225 on sidewalls of each pillar pattern.

Referring to FIGS. 1D and 1E, a photoresist layer is formed on the semiconductor substrate 200 including the pillar patterns 210 and patterned through an exposure and development process to form a photoresist pattern 230 exposing the first spacer 225.

Subsequently, a cleaning process is performed using the photoresist pattern 230 as a mask to remove the exposed first spacer 225, thereby forming an OSC 235.

Referring to 1F, the photoresist pattern 230 is removed following the formation of OSC 235.

Referring to FIG. 1G, a bit line pattern 240 is formed between the pillar patterns 210 on the semiconductor substrate 200.

Referring to FIG. 1H, silicon is grown on each pillar pattern 210 to form silicon patterns 250 on the pillar patterns 210.

Referring to FIG. 1I, an insulating layer 260 is formed above the bit line pattern 240 between the pillar patterns 210.

Subsequently, a gate pattern 270 may be formed on the pillar patterns 210 and a storage node contact (SNC) plug 280 may be formed on the silicon pattern 250.

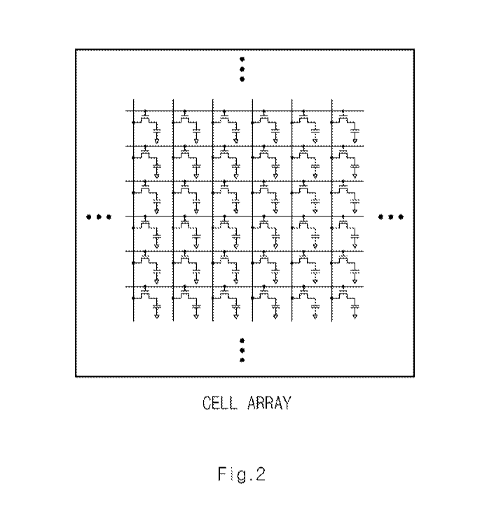

FIG. 2 is a block diagram illustrating a configuration of a cell array according to an exemplary embodiment of the present invention.

Referring to FIG. 2, a cell array includes a plurality of memory cells and each memory cell includes one transistor and one capacitor. The memory cells are disposed at intersections of bit lines BL1, . . . , BLn and word lines WL1, . . . , WLm, respectively. The memory cells store or output data based on voltages applied to a corresponding bit line of the bit lines BL1, . . . , BLn and a corresponding word line of the word lines WL1, . . . , WLm selected by the column decoder and row decoder (not shown).

As shown in FIG. 2, in the cell array, the bit lines BL1, . . . , BLn are formed in a first direction (bit line direction) as a length direction and the word lines WL1, . . . , WLm are formed in a second direction (word line direction) as a length direction so that the bit lines BL1, . . . , BLn and the word lines WL1, . . . , WLm are disposed to intersect each other. A first terminal (for example, a drain terminal) of the transistor is connected to a corresponding bit line of the bit lines BL1, . . . , BLn, a second terminal (for example, a source terminal) is connected to the capacitor, and a third terminal (for example, a gate terminal) is connected to a corresponding word line of the word lines WL1, . . . , WLm. The bit lines BL1, . . . , BLn and the word lines WL1, . . . , WLm, and the plurality of memory cells are disposed within the semiconductor cell array.

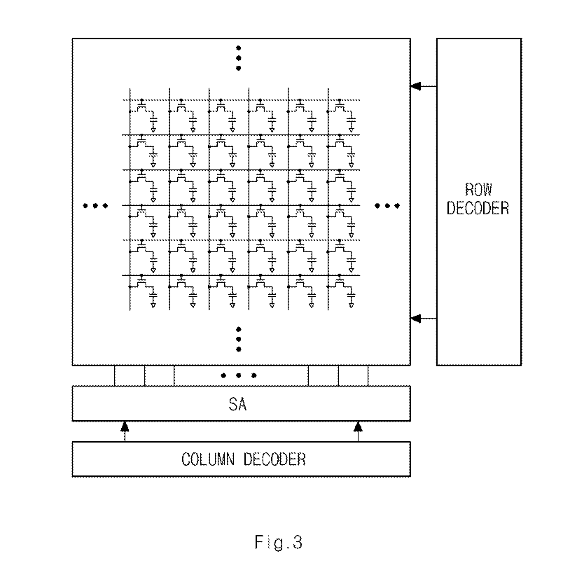

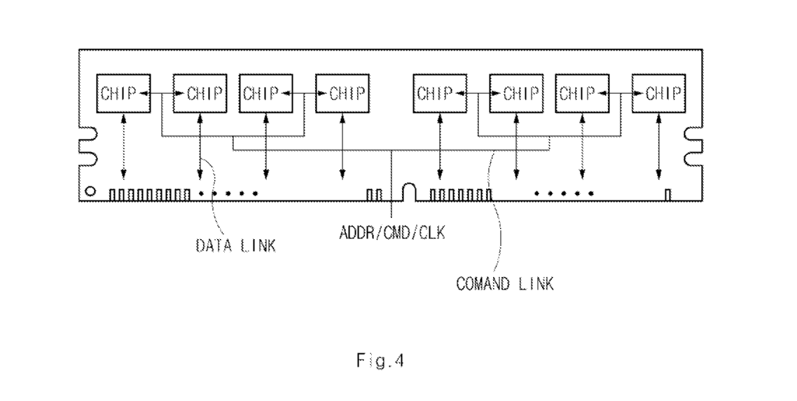

FIG. 3 is a block diagram illustrating a configuration of a semiconductor device according to an exemplary embodiment of the present invention.

Referring to FIG. 3, the semiconductor device may include a semiconductor cell array, a row decoder, a column decoder, and a sense amplifier (SA). The row decoder selects a word line corresponding to a memory cell in which a read or write operation is to be performed from among word lines of the semiconductor cell array and outputs a word line select signal RS to the semiconductor cell array. The column decoder selects a bit line corresponding to a memory cell in which a read or write operation is to be performed from among bit lines of the semiconductor cell array and outputs a bit line select signal CS to the semiconductor cell array. Further, the sense amplifiers sense data BDS stored in a memory cell selected by the row decoder and the column decoder.

In addition, the semiconductor device may be connected to a microprocessor or a memory controller and receives control signals such as a write enable signal (WE*), a row address strobe (RAS*) signal, and a column address strobe (CAS*) signal from a microcontroller and receives data through an input/output (I/O) circuit and stores the received data. The semiconductor device may be applied to dynamic random access memories (DRAMs), phase-change RAMs (PRAMs), magnetoresistance RAMs (MRAMs), NAND flash memories, CMOS image sensors (CISs), or the like. In particular, the semiconductor device may be applied to desktop computers, laptop computers, and servers as DRAMs. In addition, the semiconductor device may be applied to graphic memories and mobile memories. The NAND flash memory may be applied to a portable storage device such as a memory stick, a multimedia card (MMC), a secure digital (SD), a compact flash (CF), an extreme digital (xD) picture card, a universal serial bus (USB) flash device, and various digital applications such as an MP3 player, a portable multimedia player (PMP), a digital camera, a camcorder, a memory card, a USB, a gaming apparatus, a navigation system, a laptop computer, a desktop computer, and a mobile phone. The CIS is an imaging device serves as a kind of an electronic film in a digital apparatus and may be applied to a camera phone, a web camera, and a small-size medical photographing apparatus.

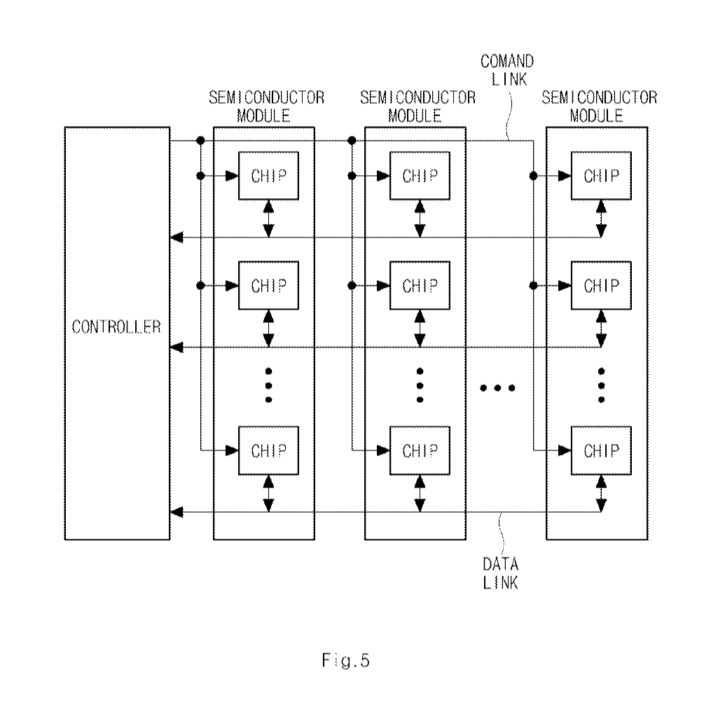

FIG. 4 is a block diagram illustrating a configuration of a semiconductor module according to an exemplary embodiment of the present invention.

Referring to FIG. 4, the semiconductor module includes a plurality of semiconductor devices mounted on a module substrate, a command link which allows the semiconductor devices to receive control signals (address signal (ADDR), command signal (CMD), clock signal (CLK)) from an external controller (not shown), and a data link which is connected to the semiconductor devices and transfers data to the semiconductor devices.

At this time, the semiconductor devices may include the semiconductor device illustrated in FIG. 3. The devices may use a conventional command link and data link.

Although FIG. 4 shows 8 semiconductor devices (or semiconductor chips) mounted on a front of the module substrate, the semiconductor devices are also mounted on a rear of the module substrate in the same manner. That is, the semiconductor devices may be mounted on one side or both sides of the module substrate and the number of semiconductor devices is not limited to the number shown in FIG. 4. In addition, material and construction of the module substrate are not specifically limited thereto.

FIG. 5 is a block diagram illustrating a configuration of a semiconductor system according to an exemplary embodiment of the present invention.

Referring to FIG. 5, the semiconductor system includes at least one semiconductor module on which a plurality of semiconductor devices are mounted and a controller configured to provide a bidirectional interface between the semiconductor module and an external system (not shown) and control the semiconductor module. The controller may be configured to control an operation of a plurality of module in a conventional data processing system. Therefore, its detailed description will be omitted herein. The semiconductor module may include the semiconductor module illustrated in FIG. 4.

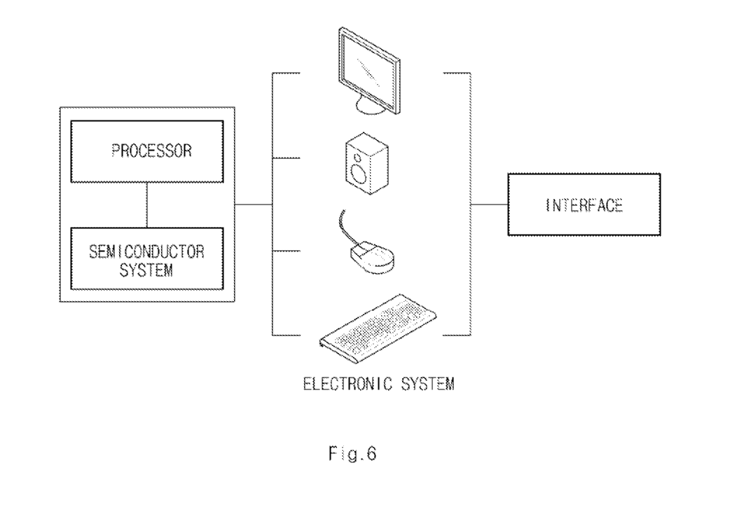

FIG. 6 is a block diagram illustrating configurations of an electronic unit and an electronic system according to an exemplary embodiment of the present invention.

Referring to a left side of FIG. 6, an electronic unit according to an exemplary embodiment includes a semiconductor system and a processor electrically connected to the semiconductor system. The semiconductor system may have the same configuration as the semiconductor system of FIG. 5. Here, the processor includes a central processing unit (CPU), a micro processor unit (MPU), a micro controller unit (MCU), a graphics processing unit (GPU) or a digital signal processor (DSP).

Here, the CPU or MPU has a combined form of an arithmetic logic unit (ALU) which is an arithmetic and logical operation unit and a control unit (CU) which reads and interprets commands to control each unit. When the processor is CPU or MPU, the electronic unit may include computer appliances or mobile appliances. Further, a GPU is a CPU for graphic which is used to calculate numbers having a decimal point. The GPU is a processor which draws graphics on a screen in real time. When the processor is a GPU, the electronic unit may include graphic appliances. DSP is called as a processor which fast converts an analog signal (for example, audio) in a digital signal, calculates the converted signal, and uses the calculated result or converts the calculated result in an analog signal again. DSP typically calculates a digital value. When the processor is DSP, the electronic unit may include audio and video appliances.

In addition, the processor includes an acceleration processor unit (APU). The processor has a combined construction of CPU with GPU and serves as a graphic card.

Referring to a right side of FIG. 6, an electronic system includes an electric unit and at least one interface electrically connected to the electronic unit. At this time, the electronic unit has the same configuration as the electronic unit of FIG. 6. Here, the interface may include a monitor, a keyboard, a pointing device (mouse), a USB, a switch, a card reader, a keypad, a dispenser, a phone, a display, or a speaker. However, the present invention is not limited to these embodiments.

As described above, according to the exemplary embodiment, after first and second spacers are formed on sidewalls of a pillar pattern and a photoresist pattern exposing the first spacer is formed on a semiconductor substrate including the pillar pattern and the spacers, processes for removing the first spacer to form an OSC, removing the photoresist pattern, forming a bit line between the pillar patterns, forming an epitaxial layer on the pillar pattern, and forming a vertical gate and a SNC. Thus, a process for forming the OSC can be simplified. In addition, the OSC formation process is performed to a pillar pattern with a short height so that a failure such as an OSC-not-opening failure can be prevented.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method of manufacturing a semiconductor device, comprising:
forming a pillar pattern on a semiconductor substrate;
forming first and second spacers over first and second sidewalls of the pillar pattern, respectively;
removing the first spacer to form an one-side-contact (OSC);
forming a bit line pattern between the pillar pattern and a neighboring pillar pattern so that the bit line pattern is coupled to the first sidewall of the pillar pattern;
forming a silicon pattern by growing silicon on the pillar pattern; and
forming a gate pattern coupled to the silicon pattern.

2. The method of claim 1, wherein the step of forming the pillar pattern includes:
forming a photoresist pattern on the semiconductor substrate; and
etching the semiconductor substrate using the photoresist pattern as an etch mask to from the pillar pattern.

3. The method of claim 1, wherein the step of forming the pillar pattern includes anisotropically etching the semiconductor substrate.

4. The method of claim 1, wherein the step of forming the first and the second spacers includes:
forming a liner insulating layer on the pillar pattern and the semiconductor substrate; and
etching back the liner insulating layer until the pillar pattern is exposed.

5. The method of claim 1, wherein the step of forming the OSC includes removing the first spacer by a cleaning process.

6. The method of claim 1, wherein the step of forming the one-side-contact(OSC) includes:
forming a photoresist pattern exposing the first spacer;
removing the first spacer using the photoresist pattern as a barrier layer.

7. The method of claim 6, wherein the step of forming the photoresist pattern includes forming the photoresist pattern exposing the first spacer over the first sidewall of the pillar pattern and shielding the second spacer over the second sidewall of each pillar pattern.

8. The method of claim 1, the method further comprising:
after forming a gate pattern,
forming a storage node contact coupled to the silicon pattern.

9. A semiconductor device, comprising:
a pillar pattern disposed on a semiconductor substrate;
a spacer disposed over a first sidewall of the pillar pattern;
a one-side-contact (OSC) disposed over a second sidewall of the pillar pattern;
a bit line pattern coupled to the OSC over the second sidewall of the pillar patterns;
a silicon pattern disposed on the pillar pattern; and
a gate pattern coupled to the silicon pattern.

10. The semiconductor device of claim 9, wherein the first and the second spacers each include an insulating layer.

11. The semiconductor device of claim 9, the device further comprising:
a storage node contact coupled to the silicon pattern.

12. A method of manufacturing a semiconductor device, comprising:
forming a lower pillar pattern over a substrate;
forming first and second spacers over first and second sidewalls of the lower pillar pattern, respectively;
removing the first spacer to expose the first sidewall of the lower pillar pattern;
forming a bit line pattern coupled to the first sidewall of the lower pillar pattern; and
forming an upper pillar pattern extending upward from the lower pillar pattern.

13. The method of claim 12,
wherein the upper pillar pattern is formed by an epitaxial growing method.

14. The method of claim 12, the method further comprising:
forming a gate pattern at a sidewall of the upper pillar pattern.

15. The method of claim 12, the method further comprising:
forming a storage node contact coupled to the upper pillar pattern.

16. The method of claim 12,
wherein the upper pillar pattern includes an epitaxial semiconductor layer.

17. The method of claim 12,
wherein the lower pillar pattern includes any of a polysilicon layer, an epitaxial silicon layer, a germanium layer, and a Si—Ge composite layer; and
wherein the upper pillar pattern 250 includes any of an epitaxial silicon layer, an epitaxial germanium layer, and an epitaxial Si—Ge composite layer.

18. The method of claim 12,
wherein the lower pillar pattern is formed by patterning the substrate, and
wherein the upper pillar pattern is formed by an epitaxial growth method.

19. The method of claim 12,
wherein the lower pillar pattern and the upper pillar pattern are formed by different processes.

20. A semiconductor device, comprising:
a lower pillar pattern extending upward from a substrate;
an upper pillar pattern extending upward from the lower pillar pattern, wherein the upper pillar pattern includes a pattern epitaxially grown from the lower pillar pattern; and
a first bit line pattern coupled to a first sidewall of the lower pillar pattern.

21. The semiconductor device of claim 20, the device further comprising:
a second bit line pattern formed over a second sidewall of the lower pillar pattern; and
a spacer formed between the second bit line pattern and the second sidewall of the lower pillar pattern.

22. The semiconductor device of claim 20,
wherein the lower and the upper pillar patterns have different electrical properties from each other.

23. The semiconductor device of claim 20,
wherein the upper pillar pattern includes an epitaxial semiconductor layer.

24. The semiconductor device of claim 20,
wherein the lower pillar pattern includes any of a polysilicon layer, an epitaxial silicon layer, a germanium layer, and a Si—Ge composite layer; and
wherein the upper pillar pattern includes any of an epitaxial silicon layer, an epitaxial germanium layer, an epitaxial Si—Ge composite layer.

25. The semiconductor device of claim 20, the device further comprising:
a gate pattern coupled to the upper pillar pattern.

26. The semiconductor device of claim 20, the device further comprising:
a storage node contact coupled to the upper pillar pattern.
